(19) United States
(12) Patent Application Publication
(10) Pub. No.: US 2026/0239545 A1
(43) Pub. Date: Aug. 13, 2026

(54) SECURITY APPARATUS FOR SECURE DISPLAY OF A PORTABLE ELECTRONIC DEVICE AND ASSOCIATED METHOD

(71) Applicant: SCORPION SECURITY PRODUCTS, INC., Vestal, NY (US)

(72) Inventors: Patrick McEwen, Greene, NY (US); Franklyn W. Gulick, JR., Binghamton, NY (US); Joshua Buttacavoli, Binghamton, NY (US); Grant Gulick, Endwell, NY (US)

(73) Assignee: SCORPION SECURITY PRODUCTS, INC., Vestal, NY (US)

(21) Appl. No.: 19/539,310

(22) Filed: Feb. 13, 2026

Related U.S. Application Data
(60) Provisional application No. 63/758,117, filed on Feb. 13, 2025.

(51) Int. Cl. H05K 5/02; G04G 17/08; G06F 1/16; G06F 1/26; G08B 13/00; H02J 50/10

(52) U.S. Cl. CPC H05K 5/0208; G04G 17/08; G06F 1/1629; G08B 13/00; H02J 50/10; H05K 5/0204; H05K 5/0247; G06F 1/163; G06F 1/26

(57) ABSTRACT

A security apparatus for secure display of a portable electronic device includes a base structured to be secured to a display fixture and a retainer that removably couples to the base to define a secured state and an unsecured state. the retainer includes a support structured to at least partially support a rear surface of a body of the portable electronic device and at least one retaining member structured to retain a portion of the portable electronic device. In the secured state, the base and the retainer are coupled together and cooperate to inhibit removal of the portable electronic device from the security apparatus. In the unsecured state, the portable electronic device may be removed from the security apparatus.

### CROSS-REFERENCE OT RELATED APPLICATION

This application claims priority to, and the benefit of, U.S. Provisional Patent Application Ser. No. 63/758,117, filed on Feb. 13, 2025. The entire contents of said application are incorporated by reference.

### TECHNOLOGICAL FIELD

This invention relates generally to the field of security apparatuses used to secure portable electronic devices in a retail setting for display purposes and specifically to a security apparatus for secure display of a smart watch in a retail setting.

### BACKGROUND

Retailers sell a portable electronic device such as smart watches that can assist in or perform a multitude of tasks for a user or customer. Part of the shopping experience for said devices is having the ability to examine and test the electronic device in the retail setting prior to purchase. This is done using floor models that are fitted with some form of security apparatus to prevent theft of the electronic device.

There are many different types of security apparatuses used in retail settings, however most are not suitable for all types of electronic devices, especially small portable electronic devices, such as smart watches.

These are just some of the problems associated with current security apparatuses for handheld or portable electronic devices.

### SUMMARY OF THE INVENTION

Aspects of the disclosure are directed to embodiments of a security apparatus for secure display of a portable electronic device including a base and a retainer removably coupled to the base to define a secured state and an unsecured state. In some embodiments, the base defines a recess surrounded by a rim. In some embodiments, the recess includes a support surface and at least one coupler extending from the base and structured to secure the base to a display fixture. In some embodiments, the retainer includes a support structured to at least partially support a rear surface of a body of the portable electronic device and at least one retaining member positioned to retain a portion of the body of the portable electronic device against the support. In some embodiments, when in the secured state, the retainer is coupled to the recess of the base and the body of the portable electronic device is retained between the at least one retaining member, the support surface, and the base such that the body of the portable electronic device is inhibited from being removed from the security apparatus. In some embodiments, when in the unsecured state, the body of the portable electronic device may be removed from the security apparatus.

In some embodiments of the security apparatus, the portable electronic device is a smart watch having a body and a band, and wherein the base and the retainer are structured to interact with each other to secure the body of the smart watch while the band extends at least partially around the retainer. In some embodiments of the security apparatus, the rim surrounds the support surface. In some embodiments of the security apparatus, the support surface extends along a first plane and a surface of the display fixture extends along a second plane when the base is secured to the surface of the display fixture, the first plane intersects the second plane at an angle of less than 90°. In some embodiments, the security apparatus further includes a seat member structured to be positioned on the support surface and to define a depression that at least partially accepts a portion of the body of the portable electronic device. In some embodiments of the security apparatus, when in the secured state, the body of the portable electronic device is secured between the seat member, the support and the at least one retaining member. In some embodiments of the security apparatus, the support extends along a third plane that intersects the first plane of the support surface at an angle that is greater than 90°. In some embodiments of the security apparatus, the least one coupler includes at least one bracket structured to secure the base to a track of the display fixture.

Aspects of the disclosure are directed to embodiments of a security apparatus for secure display of a portable electronic device including a base configured to be secured to a display fixture and a retainer configured to be removably coupled to the base to define a secured state and an unsecured state. In some embodiments, the retainer includes a support that at least partially supports a rear surface of a body of the portable electronic device and at least one retaining member that retains a portion of the portable electronic device. In some embodiments, when in the secured state, the base and the retainer are coupled together and configured to cooperate to inhibit removal of the portable electronic device from the security apparatus. In some embodiments, when in the unsecured state, the portable electronic device may be removed from the security apparatus.

In some embodiments of the security apparatus, the base defines a recess including a support surface and wherein in the secured state, the portable electronic device is retained between support surface, the at least one retaining member and the support surface. In some embodiments of the security apparatus, at least one of the base and the retainer includes a charging accessory to charge the portable electronic device while the portable electronic device is retained by the security apparatus. In some embodiments of the security apparatus, the charging accessory includes at least one of: (i) a magnetic charging cable that plugs into the portable electronic device; and (ii) a magnetic charging element that wirelessly charges the portable electronic device. In some embodiments of the security apparatus, the base includes an alarm structured to be triggered when the portable electronic device is removed from the security apparatus. In some embodiments, the security device further includes a seat member structured to be positioned on the support surface and to define a depression that at least partially accepts a portion of the body of the portable electronic device. In some embodiments of the security apparatus, when in the secured state, the body of the portable electronic device is secured between the seat member, the support and the at least one retaining member.

Aspects of the disclosure are further directed to embodiments of a method of manufacturing a security apparatus for a portable electronic device including structuring a base to be secured to a display fixture and structuring a retainer to be removably coupled to the base and to define a secured state and an unsecured state. In some embodiments, the method includes structuring the retainer include a support structured to at least partially support a rear surface of a body of the portable electronic device and at least one retaining member to retain a portion of the body of the portable electronic device. In some embodiments, the method includes structuring the base and the retainer to be coupled together in the secured state and to cooperate to inhibit removal of a body of the portable electronic device from the security apparatus, and to enable removal of the body of the portable electronic device when in the unsecured state.

In some embodiments, the method further includes structuring the base to define a recess including a support surface, and structuring the retainer such that, in the secured state, the portable electronic device is retained between the support, the at least one retaining member and the support surface. In some embodiments, the method further includes structuring at least one of the base and the retainer to include a charging accessory that charges the portable electronic device while the portable electronic device is retained by the security apparatus. In some embodiments, the method further includes structuring a seat member to be positioned on the support surface and to define a depression that at least partially accepts a portion of the body of the portable electronic device. In some embodiments of the method, when in the secured state, the body of the portable electronic device is secured between the seat member, the support and the at least one retaining member

### BRIEF DESCRIPTION OF DRAWINGS

A more particular description of the invention briefly summarized above may be had by reference to the embodiments, some of which are illustrated in the accompanying drawings. It is to be noted, however, that the appended drawings illustrate only typical embodiments of this invention and are therefore not to be considered limiting of its scope, for the invention may admit to other equally effective embodiments. Thus, for further understanding of the nature and objects of the invention, references can be made to the following detailed description.

FIG. 1 illustrates a front perspective view of an embodiment of a security apparatus for secure display of a portable electronic device with an embodiment of a portable electronic device being retained, according to aspects of the following disclosure.

FIG. 2 illustrates a front perspective view of an embodiment of a security apparatus for secure display of a portable electronic device and secured to a display fixture, according to aspects of the following disclosure.

FIG. 3 illustrates a side view of the embodiment of FIG. 2 showing a coupler extending from the security apparatus between an upper surface and an under surface of the display fixture.

FIG. 4 illustrates a front view of the embodiment of FIG. 3.

FIG. 5 illustrates a rear view of the embodiments of FIGS. 3 and 4.

FIG. 6 illustrates a top view of the embodiment of FIGS. 3-5.

FIG. 7 illustrates an exploded view of an embodiment of the security apparatus for secure display of a portable electronic device, according to aspects of the following disclosure.

FIG. 8 illustrates an exploded view of another embodiment of a security apparatus for secure display of a portable electronic device, according to aspects of the following disclosure.

FIG. 9 illustrates a partially exploded view of the embodiment of FIG. 8.

FIG. 10 illustrates a side view of an embodiment of a security apparatus for secure display of a portable electronic device, according to aspects of the following disclosure.

FIG. 11 illustrates a side view of another embodiment of the security apparatus for secure display of a portable electronic device, according to aspects of the following disclosure.

FIG. 12 illustrates a perspective top view of another embodiment of the security apparatus for secure display of a portable electronic device, according to aspects of the following disclosure.

### DETAILED DESCRIPTION

The following discussion relates to various embodiments of a security apparatus for secure display of a portable electronic device, such as a smart watch. It will be understood that the herein described versions are examples that embody certain inventive concepts as detailed herein. To that end, other variations and modifications will be readily apparent to those of sufficient skill. In addition, certain terms are used throughout this discussion in order to provide a suitable frame of reference with regard to the accompanying drawings. These terms such as “upper”, “lower”, “forward”, “rearward”, “interior”, “exterior”, “front”, “back”, “top”, “bottom”, “inner”, “outer”, “first”, “second”, and the like are not intended to limit these concepts, except where so specifically indicated. The terms “about” or “approximately” as used herein may refer to a range of 80%-125% of the claimed or disclosed value. With regard to the drawings, their purpose is to depict salient features of the security apparatus for secure display of a portable electronic device and are not specifically provided to scale.

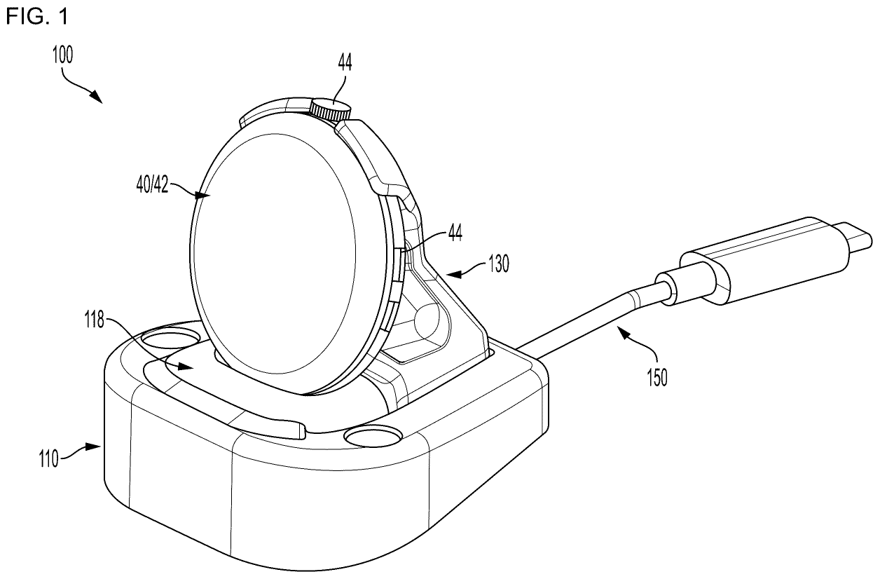

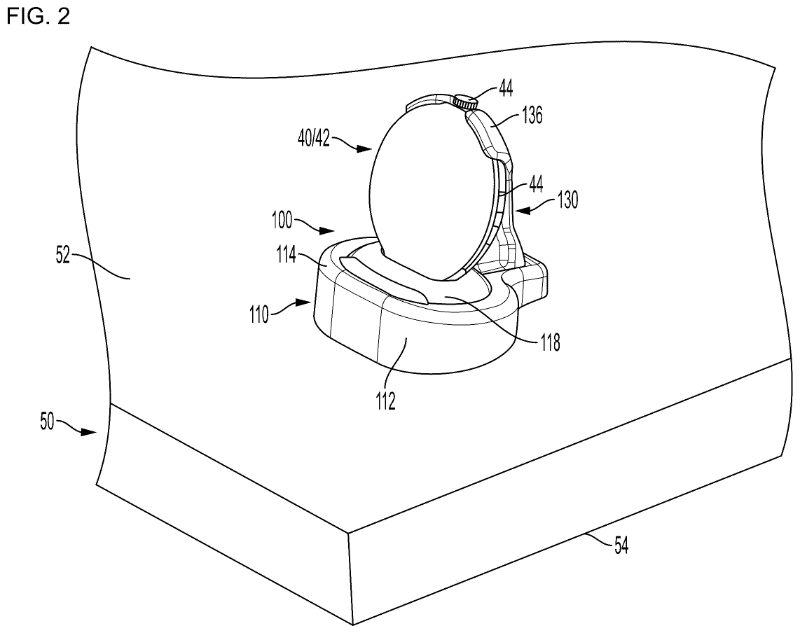

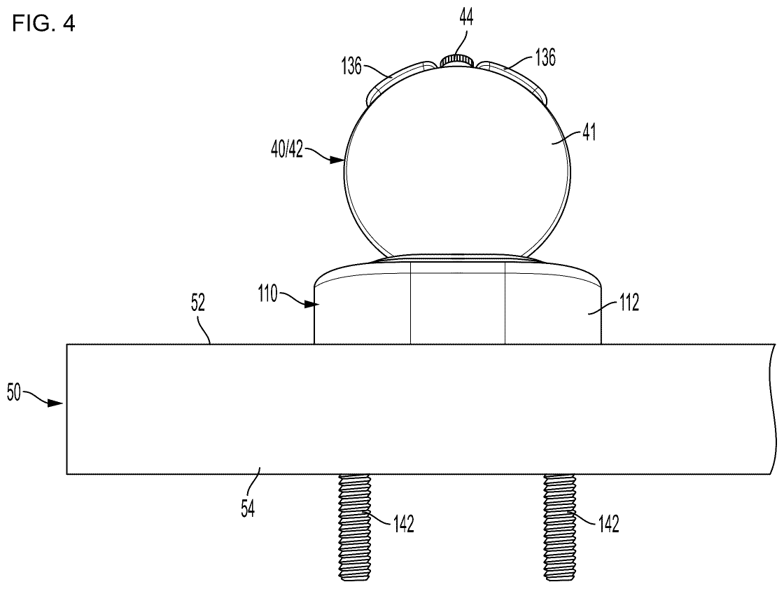

Referring to FIGS. 1-6, an embodiment of a security apparatus for the secure display of a portable electronic device 100 (security apparatus) is shown securing an embodiment of a portable device, such as a smart watch 40. In other embodiments, the portable electronic device may comprise, for example, a fitness tracker, a compact media player, a small camera, or another handheld electronic device having a body that can be supported/secured by the security apparatus 100. In some embodiments, the security apparatus 100 includes a base 110 structured to be coupled to or otherwise secured to a display fixture 50 and a retainer 130 removably coupled to the base 110. In some embodiments, the base 110 and/or the retainer 130 includes a charging accessory 150. In some embodiments, the charging accessory 150 includes or is electrically coupled to a magnetic charging device 90 that is structured to be electrically coupled to an electrical source and wirelessly charge the portable electronic device 40 secured in the security apparatus 100. In some embodiments, the magnetic charging device comprises a magnetic charging cable that plugs into the portable electronic device 40 and/or a magnetic charging element configured to wirelessly charge the portable electronic device 40 while is it secured in the security apparatus 100.

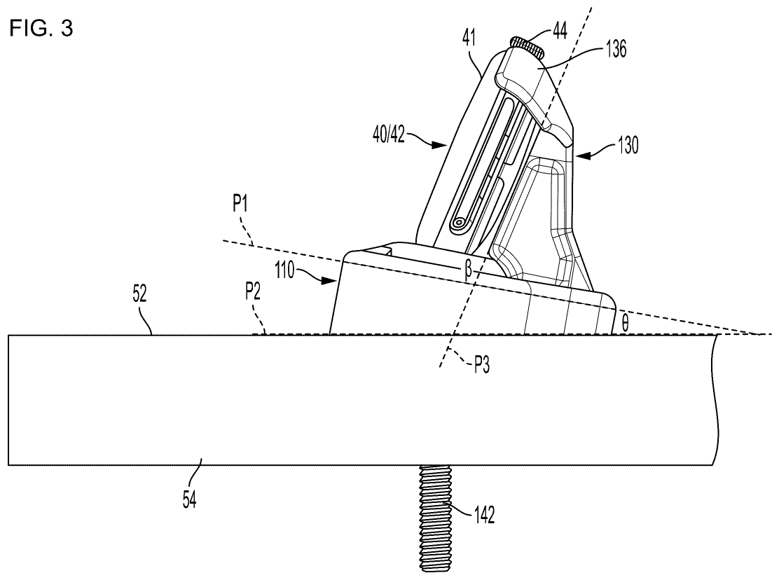

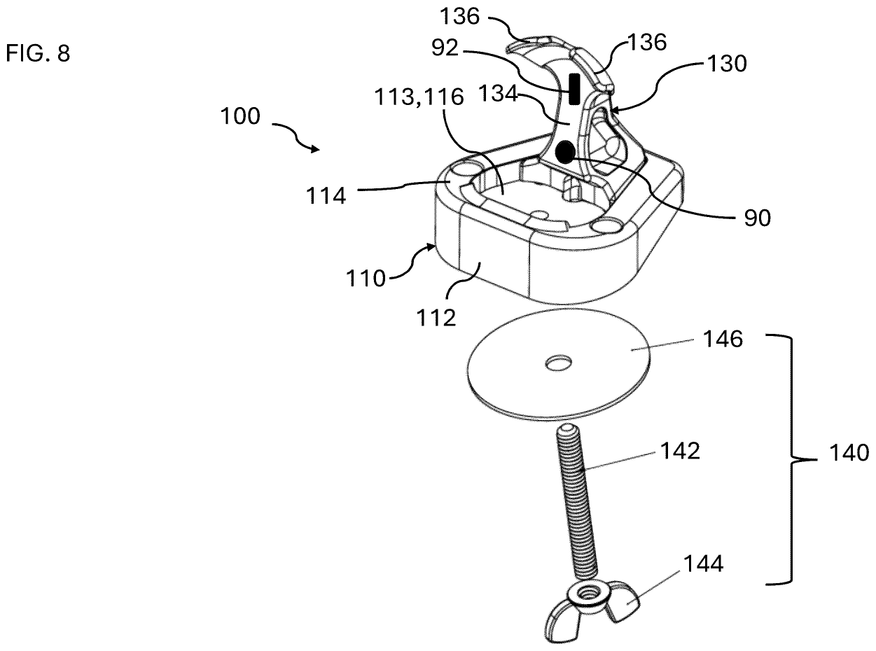

As shown in FIGS. 1-9, the security apparatus 100 generally includes a base 110 and a retainer 130 removably coupled to the base 110. In some embodiments, the base 110 includes a body 112 that defines a recess 113 including a support surface 116 and surrounded by an edge or rim 114. In some embodiments, when the base is coupled to a display fixture 50, the support surface 116 extends along a first plane P1 and an upper surface 52 of the display fixture 50 extends along a second plane P2 that intersects the first plane P1 at an angle θ (FIG. 3). In some embodiments, the angle θ is less than 90°. In some embodiments, the angle θ is less than 60°. In some embodiments, the angle θ is about 30°. In some embodiments, the base 110 includes a seat member 118 configured to at least partially support the portable electronic device, such as the smart watch 40. In some embodiments, the seat member 118 includes a depression 119 dimensioned to receive a portion of the portable electronic device 40. In some embodiments, the seat member 118 is configured to removably couple to the base 110. In some embodiments, the seat member is formed as part of the base 110. In some embodiments, the support surface 116 defines the depression 119 that is dimensioned to receive a portion of the portable electronic device 40.

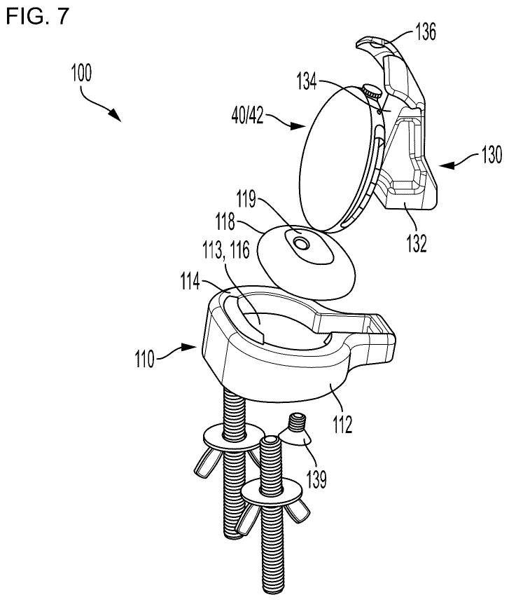

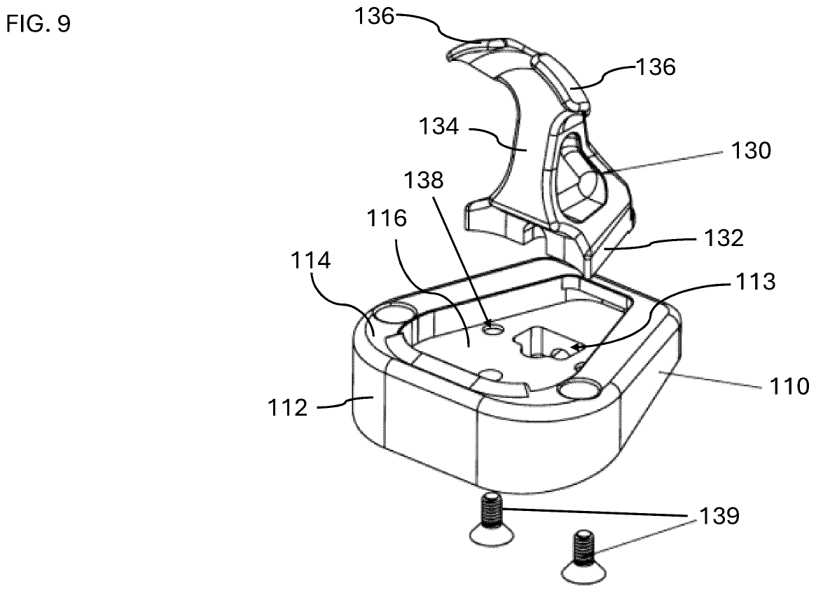

The retainer 130 is structured to be removably coupled to the base 110. In some embodiments, the retainer 130 is configured to removably couple to the body rim 114 and/or the support surface 116 of the base 110. In some embodiments, the retainer 130 abuts or is at least partially positioned against the body rim 114. In some embodiments, the retainer 130 includes a coupling interface 132, a support 134 configured to at least partially support a portion of the portable electronic device 40, and at least one retaining member 136 structured to retain a portion of portable electronic device 40. In some embodiments, the support 134 at least partially supports a rear side 43 of the body 43 of the portable electronic device. In some embodiments, the coupling interface 132 is structured to interact with the base 110 to removably couple the retainer 130 to the base 110. In some embodiments, the retainer 130 is secured to the base via one or more couplers 139 as shown in FIG. 7. In some embodiments, the one or more couplers 139 may include a fastener, such as a screw or safety screw. In some embodiments, such as shown in FIG. 9, the one or more couplers 139 are at least partially accepted by a coupling element 138, such as a bore or threaded bore that interacts with the screw.

Securing the portable electronic device 40 in the security apparatus 100 will now be discussed with reference to FIGS. 1-9. When the security apparatus 100 is detached from a display fixture 50, the one or more couplers 139 are accessible and able to be actuated or removed from the base 110 to enable separation of the base 110 from the retainer 130. In some embodiments, the retainer 130 is removably coupled to the base 110 using one or more fasteners 139 that couple the coupling interface 132 of the retainer 130 to the base 110. In some embodiments, the coupling interface 132 of the retainer 130 includes one or more securing features that are structured to interact with complementary securing features 113 of the base 110 to further provide a secure coupling between the retainer 130 and the base 110. Once the retainer 130 is removed from the base 110, the portable electronic device 40 may be positioned in the security apparatus 100. In the embodiments shown, the security apparatus 100 is structured to secure the body 42 of the portable electronic device 40. In embodiments when the portable electronic device 40 is a smart watch, the band (not shown) of the smart watch may be positioned at least partially around the support 134 of the retainer 130. In some embodiments, the body 42 of the portable electronic device 40 may be partially positioned on the support surface 116 and the retainer 130 is positioned such that the body 42 of the portable electronic device 40 is supported by the support surface 116 and the support 134 of the retainer 130. In some embodiments, the support 134 extends along a third plane P3 that intersects the first plane P1 of the support surface 116 at an angle β relative to the support surface. In some embodiments, the angle β is greater than 90°. Accordingly, when the security apparatus 100 is secured to or positioned on the display fixture 50, the body of the portable electronic device 40 is angularly positioned so that a front surface 41 of the body 42 of the portable electronic device 40 faces up towards the customer's gaze. When the retainer 130 is secured to the base 110, the body 42 of the smart watch 40 is secured between the one or more retaining members 136 and the support surface 116 of the base. Referring to the embodiment of FIG. 7, the body 42 of the portable electronic device 40 is secured between the support 134, the one or more retaining members 136 and the seat member 118.

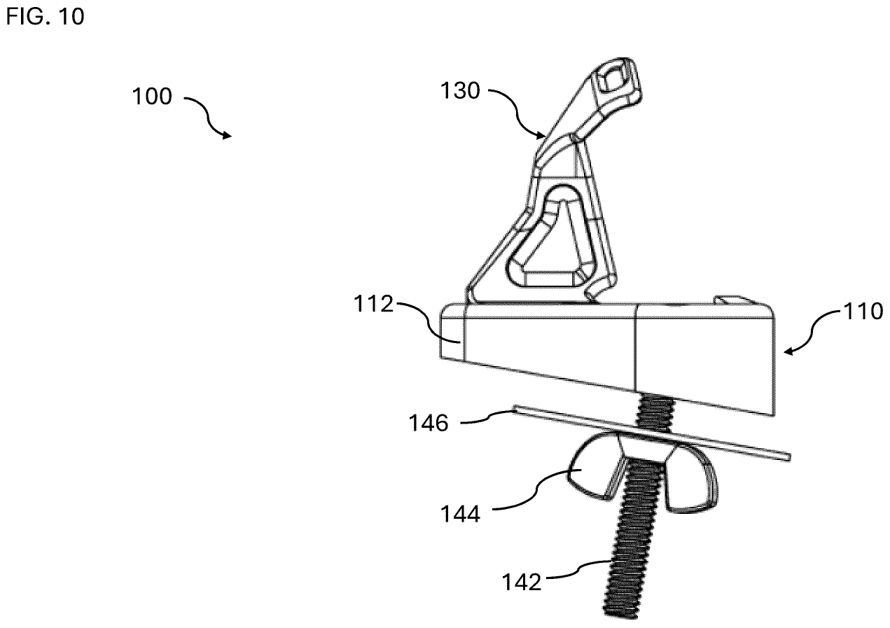

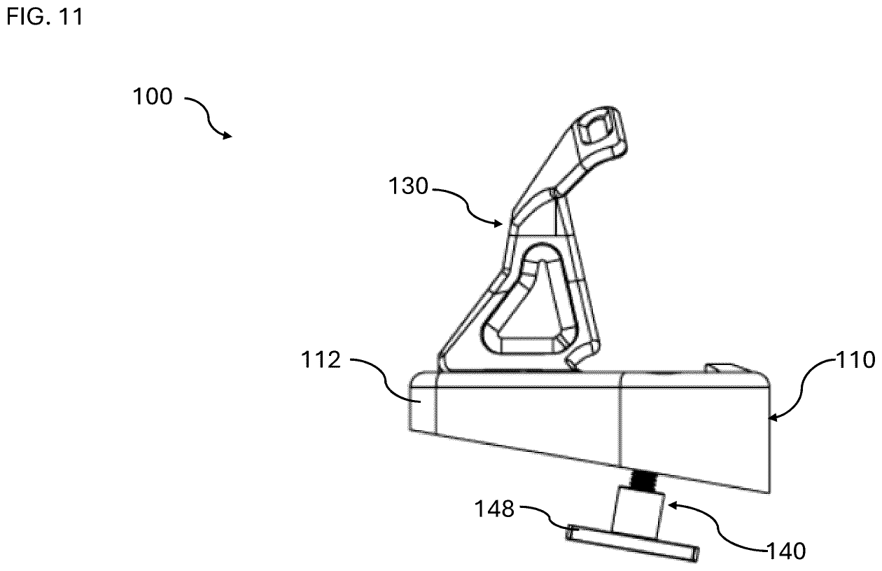

When the body 42 of the portable electronic device 40 is secured in the security apparatus 100, the body 42 is inhibited from being pulled away or otherwise removed from the security apparatus 100. The security apparatus 100 may then be coupled to a display fixture 50 via one or more attachment assemblies 140 such that the portable electronic device 40 is secured to the display fixture 50. Referring to FIGS. 3-5, 7, 8, 10, the one or more attachment assemblies 140 comprise a threaded extension 142 that extends from the base 110 and is structured to extend from the upper surface 52 of the display fixture 50 to an under surface 54 of the display fixture 50. In some embodiments, a locking member 144 is configured to interact with the one or more coupling assemblies 140 to secure the security apparatus 100 to the display fixture 50. In some embodiments, the one or more coupling assemblies 140 includes one or more washers 146 that are structured to be positioned between the under surface 54 of the display fixture 50 and the locking member 144. Referring to the embodiment shown in FIG. 11, the one or more coupling assemblies 140 may include at least one bracket 148 structured to secure the security apparatus 100 to the display fixture 50. In some embodiments, the bracket 148 is structured to cooperate or otherwise fit in or on a track (not shown) attached to or formed on the display fixture 50. In some embodiments, other coupling assemblies 140 may include one or more different types of extensions 142 and locking members 144 that function in a similar manner to secure the security of apparatus 100 to different types of display fixtures 50, including fixtures having through-holes and fixtures having tracks.

In some embodiments, the base 110 includes an alarm 92 that is triggered when the portable electronic device 40 is removed from the security apparatus 100. In some embodiments, the alarm In some embodiments, the one or more retaining members 136 may define one or more openings configured to fit around or provide access to one or more inputs 44 of the body 42 of the smart watch 40. Components of the embodiments of the security apparatus 100 may be comprised of a metal and/or a metal alloy and/or one or more polymers. Some of the components of the security apparatus 100 discussed may be formed together as a single component. In some embodiments, the base 110 and a portion of the one or more coupler assemblies 140 are formed as a single, unitary component.

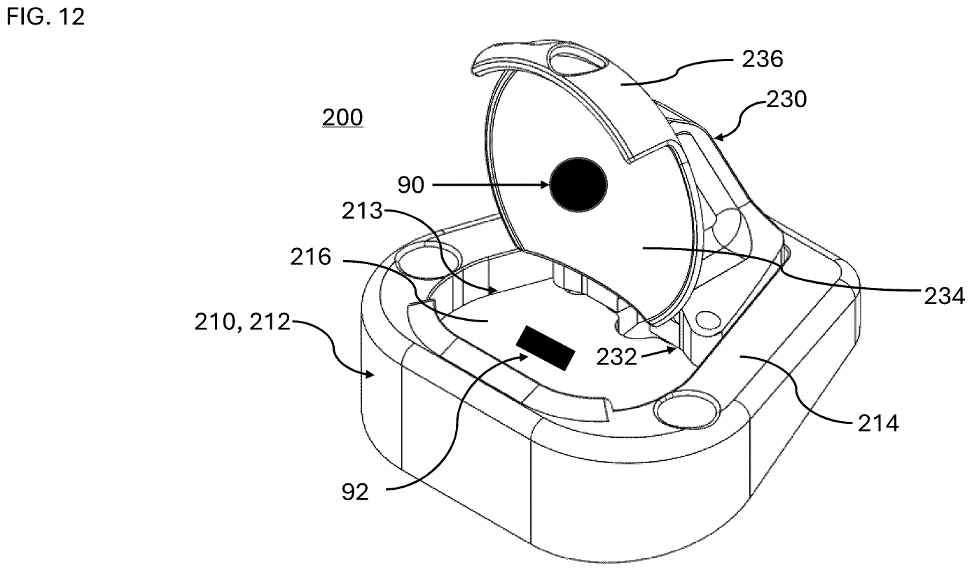

Referring to FIG. 12, another embodiment of the security apparatus 200 is shown. In some embodiments, the security apparatus 200 includes a base 210 as in previously described embodiments that is structured to be coupled to or otherwise secured to a display fixture 50 and a retainer 230 removably coupled to the base 210. In some embodiments, the base 210 and/or the retainer 230 includes a charging accessory 250. In some embodiments, the charging accessory 250 is similar to the charging accessory 150 of previously described embodiments. In some embodiments, the charging accessory 150 includes or is electrically coupled to a magnetic charging device 90 that is structured to be electrically coupled to an electrical source and wirelessly charge the portable electronic device secured in the security apparatus 200. In some embodiments, the magnetic charging device 90 comprises a magnetic charging cable 250 that plugs into the portable electronic device 40 and/or a magnetic charging element configured to wirelessly charge the portable electronic device while is it secured in the security apparatus 200, similar to previously described embodiments.

As shown in the embodiment of FIG. 12, the security apparatus 200 generally includes a base 210 and a retainer 230 removably coupled to the base 210. In some embodiments, the base 210 includes a body 212 that defines a recess 213 including a support surface 216 and surrounded by an edge or rim 214. In some embodiments, the base 210 includes a seat member (not shown) similar to embodiments previously discussed and that is structured to at least partially support the portable electronic device. In some embodiments, the support surface 216 defines the depression that is dimensioned to receive a portion of the portable electronic device.

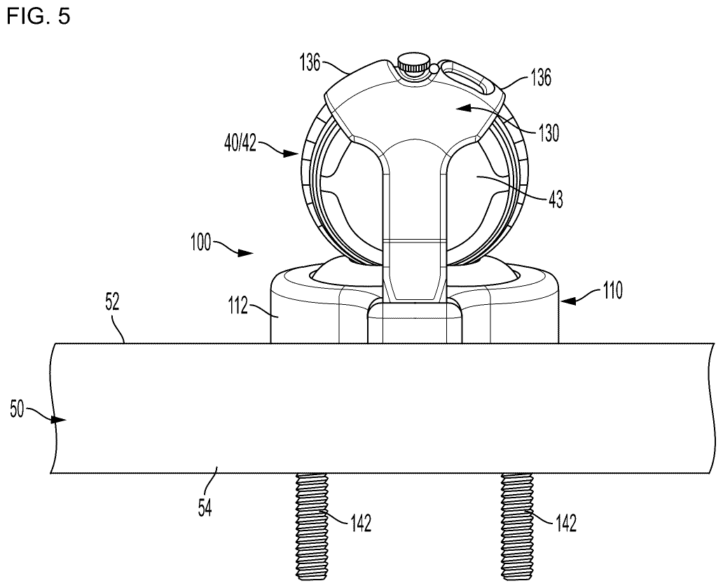

Still referring to the embodiment shown in FIG. 12, the retainer 230 is structured to be removably coupled to the base 210. In some embodiments, the retainer 230 is configured to removably couple to the body rim 214 and/or the support surface 216 of the base 210. In some embodiments, the retainer 230 abuts or is at least partially positioned against the body rim 214. In some embodiments, the retainer 230 includes a coupling interface 232, a support 234 configured to at least partially support a portion of the portable electronic device, and at least one retaining member 236 structured to retain a portion of the portable electronic device. In some embodiments, the support 234 may be dimensioned to entirely cover a rear 43 (FIG. 5) or back side of the body of the portable electronic device to inhibit access when the portable security device is secured in the security apparatus 200. In some embodiments, the coupling interface 232 is structured to interact with the base 210 to removably couple the retainer 230 to the base 210. In some embodiments, the retainer 230 is secured to the base 210 via one or more couplers similar to those in embodiments previously discussed.

Securing the portable electronic device in the security apparatus 200 may be done in a similar manner as previously described. When the retainer 230 is secured to the base 210, the body of the portable electronic device is secured between the one or more retaining members 236 and the support surface 216 of the base 210. Referring to the embodiment of FIG. 12, the body of the portable electronic device is secured between the support 234, the one or more retaining members 236 and the seat member.

When the body 42 (FIGS. 1-7) of the portable electronic device 40 (FIGS. 1-7) is secured in the security apparatus 200, the body 42 is inhibited from being pulled away or otherwise removed from the security apparatus 200. The security apparatus 200 may then be coupled to a display fixture 50 (FIGS. 1-6) via one or more attachment assemblies such that the portable electronic device 40 (FIGS. 1-7) is secured to the display fixture 50 (FIGS. 1-6). In some embodiments, the one or more attachment assemblies are similar to those of previously discussed embodiment.

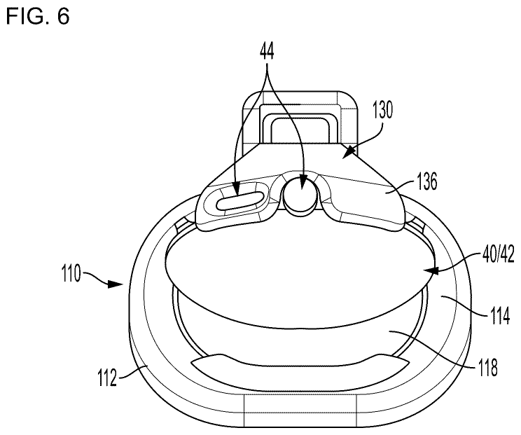

In some embodiments, the base 210 includes an alarm 92 that is triggered when the portable electronic device 40 (FIGS. 1-7) is removed from the security apparatus 200. In some embodiments, the alarm In some embodiments, the one or more retaining members 236 may define one or more openings configured to fit around or provide access to one or more inputs 44 (FIG. 6) of the body 42 (FIGS. 1-7) of the smart watch 40 (FIGS. 1-7). Components of the embodiments of the security apparatus 200 may be comprised of a metal and/or a metal alloy and/or one or more polymers. Some of the components of the security apparatus 200 discussed may be formed together as a single component. In some embodiments, the base 210 and a portion of the one or more coupler assemblies are formed as a single, unitary component as in previously discussed embodiments.

While the present invention has been particularly shown and described with reference to certain exemplary embodiments, it will be understood by one skilled in the art that various changes in detail may be affected therein without departing from the spirit and scope of the invention that can be supported by the written description and drawings. Further, where exemplary embodiments are described with reference to a certain number of elements, it will be understood that the exemplary embodiments can be practiced utilizing either less than or more than the certain number of elements. Although certain embodiments are described with reference to a smart watch, the security apparatus and associated methods described herein may be used with other portable electronic devices having a body and, optionally, a band or other support structure.

1. A security apparatus for secure display of a portable electronic device, comprising:
a base defining a recess surrounded by a rim, the recess including,
a support surface; and
at least one coupler extending from the base and structured to secure the base to a display fixture; and
a retainer removably coupled to the recess of the base to define a secured state and an unsecured state, the retainer including,
a support structured to at least partially support a rear surface of a body of the portable electronic device, and
at least one retaining member positioned to retain a portion of the body of the portable electronic device against the support,
wherein in the secured state, the retainer is coupled to the recess of the base and the body of the portable electronic device is retained between the at least one retaining member, the support surface, and the base such that the body of the portable electronic device is inhibited from being removed from the security apparatus, and
wherein in the unsecured state, the body of the portable electronic device may be removed from the security apparatus.

2. The security apparatus of claim 1, wherein the portable electronic device comprises a smart watch having a body and a band, and wherein the base and the retainer are structured to interact with each other to secure the body of the smart watch while the band extends at least partially around the retainer.

3. The security apparatus of claim 1, wherein the rim surrounds the support surface.

4. The security apparatus of claim 1, wherein the support surface extends along a first plane and a surface of the display fixture extends along a second plane, when the base is secured to the surface of the display fixture, the first plane intersects the second plane at an angle of about 30°.

5. The security apparatus of claim 1, further comprising a seat member structured to be positioned on the support surface and to define a depression that at least partially accepts a portion of the body of the portable electronic device.

6. The security apparatus of claim 5, wherein in the secured state, the body of the portable electronic device is secured between the seat member, the support and the at least one retaining member.

7. The security apparatus of claim 4, wherein the support extends along a third plane that intersects the first plane of the support surface at an angle that is greater than 90°.

8. The security apparatus of claim 1, wherein the least one coupler comprises at least one bracket structured to secure the base to a track of the display fixture.

9. A security apparatus for secure display of a portable electronic device, comprising:
a base configured to be secured to a display fixture; and
a retainer configured to be removably coupled to the base to define a secured state and an unsecured state, the retainer including,
a support configured to at least partially support a rear surface of a body of the portable electronic device, and
at least one retaining member configured to retain a portion of the portable electronic device,
wherein in the secured state, the base and the retainer are coupled together and configured to cooperate to inhibit removal of the portable electronic device from the security apparatus, and
wherein in the unsecured state, the portable electronic device may be removed from the security apparatus.

10. The security apparatus of claim 9, wherein the base defines a recess including a support surface and wherein in the secured state, the portable electronic device is retained between support surface, the at least one retaining member and the support surface.

11. The security apparatus of claim 9, wherein at least one of the base and the retainer comprises a charging accessory configured to charge the portable electronic device while the portable electronic device is retained by the security apparatus.

12. The security apparatus of claim 11, wherein the charging accessory comprises at least one of: (i) a magnetic charging cable configured to plug into the portable electronic device; and (ii) a magnetic charging element configured to wirelessly charge the portable electronic device.

13. The security apparatus of claim 9, wherein the base includes an alarm configured to be triggered when the portable electronic device is removed from the security apparatus.

14. The security device of claim 9, further comprising a seat member configured to be positioned on the support surface and to define a depression that at least partially accepts a portion of the body of the portable electronic device.

15. The security apparatus of claim 14, wherein in the secured state, the body of the portable electronic device is secured between the seat member, the support and the at least one retaining member.

16. A method of manufacturing a security apparatus for a portable electronic device, comprising:
structuring a base to be secured to a display fixture;
structuring a retainer to be removably coupled to the base and to define a secured state and an unsecured state;
structuring the retainer include,
a support configured to at least partially support a rear surface of a body of the portable electronic device, and
at least one retaining member configured to retain a portion of the body of the portable electronic device;
structuring the base and the retainer to be coupled together in the secured state and to cooperate to inhibit removal of a body of the portable electronic device from the security apparatus, and to enable removal of the body of the portable electronic device when in the unsecured state.

17. The method of claim 16, further comprising:
structuring the base to define a recess including a support surface; and
structuring the retainer such that, in the secured state, the portable electronic device is retained between the support, the at least one retaining member and the support surface.

18. The method of claim 16, further comprising structuring at least one of the base and the retainer to comprise a charging accessory configured to charge the portable electronic device while the portable electronic device is retained by the security apparatus.

19. The method of claim 17. further comprising structuring a seat member to be positioned on the support surface and to define a depression that at least partially accepts a portion of the body of the portable electronic device.

20. The method of claim 19, wherein in the secured state, the body of the portable electronic device is secured between the seat member, the support and the at least one retaining member.
